(19) United States
(12) Patent Application Publication
(10) Pub. No.: US 2012/0258580 A1
(43) Pub. Date: Oct. 11, 2012

(54) PLASMA-ASSISTED MOCVD FABRICATION OF P-TYPE GROUP III-NITRIDE MATERIALS

(75) Inventors: Karl Brown, Santa Clara, CA (US); Kevin Griffin, Livermore, CA (US); David Bour, Cupertino, CA (US); Olga Kryliouk, Sunnyvale, CA (US)

(73) Assignee: APPLIED MATERIALS, INC., Santa Clara, CA (US)

(21) Appl. No.: 13/413,009

(22) Filed: Mar. 6, 2012

Related U.S. Application Data
(60) Provisional application No. 61/451,013, filed on Mar. 9, 2011.

(51) Int. Cl. H01L 21/205; C23C 16/56; C23C 16/50

(52) U.S. Cl. 438/478; 118/723 R; 257/E21.11

(57) ABSTRACT

The plasma-assisted metal-organic chemical vapor deposition (MOCVD) fabrication of a p-type group III-nitride material is described. For example, a method of fabricating a p-type group III-nitride material includes generating a nitrogen-based plasma. A nitrogen-containing species from the nitrogen-based plasma is reacted with a group III precursor and a p-type dopant precursor in a metal-organic chemical vapor deposition (MOCVD) chamber. A group III-nitride layer including p-type dopants is then formed above a substrate.

### CROSS-REFERENCE TO RELATED APPLICATIONS

This application claims the benefit of U.S. Provisional Application No. 61/451,013, filed Mar. 9, 2011, the entire contents of which are hereby incorporated by reference herein.

### BACKGROUND

1) Field

Embodiments of the present invention pertain to the field of group III-nitride materials and, in particular, to the plasma-assisted metal-organic chemical vapor deposition (MOCVD) fabrication of p-type group III-nitride materials.

2) Description of Related Art

Group III-V materials are playing an ever increasing role in the semiconductor and related, e.g. light-emitting diode (LED), industries. Often, group III-V materials are difficult to grow or deposit without the formation of defects or cracks. For example, high quality surface preservation of select films, e.g. a gallium nitride film, is not straightforward in many applications using stacks of material layers fabricated sequentially.

### SUMMARY

One or more embodiments of the present invention are directed to a plasma-assisted metal-organic chemical vapor deposition (MOCVD) fabrication of p-type group III-nitride materials.

In an embodiment, a method of fabricating a p-type group III-nitride material includes generating a nitrogen-based plasma. A nitrogen-containing species from the nitrogen-based plasma is reacted with a group III precursor and a p-type dopant precursor in a metal-organic chemical vapor deposition (MOCVD) chamber. A group III-nitride layer including p-type dopants is then formed above a substrate.

In another embodiment, a process tool for fabricating a p-type group III-nitride material includes a plasma source for generating a nitrogen-based plasma. The process tool also includes a metal-organic chemical vapor deposition (MOCVD) chamber for reacting nitrogen-containing species from the nitrogen-based plasma with a group III precursor and a p-type dopant precursor.

### BRIEF DESCRIPTION OF THE DRAWINGS

FIG. 1 illustrates transformation of a magnesium dopant precursor molecule to form a Mg—H bond in the presence of excess hydrogen.

FIG. 2 is a Flowchart representing operations in a method of fabricating a p-type group III-nitride material, in accordance with an embodiment of the present invention.

FIG. 3 includes a SIMS depth profile plot for fabricated Mg-doped GaN, in accordance with an embodiment of the present invention.

FIG. 4 is a schematic cross-sectional view of an MOCVD chamber suitable for the fabrication of p-type group III-nitride materials, in accordance with an embodiment of the present invention.

FIG. 5 illustrates a system suitable for fabrication of p-type group III-nitride materials, in accordance with an embodiment of the present invention.

FIG. 6 illustrates a cross-sectional view of a gallium nitride (GaN)-based light-emitting diode (LED), in accordance with an embodiment of the present invention.

### DETAILED DESCRIPTION

The plasma-assisted metal-organic chemical vapor deposition (MOCVD) fabrication of p-type group III-nitride materials is described. In the following description, numerous specific details are set forth, such as MOCVD chamber configurations and material regimes, in order to provide a thorough understanding of embodiments of the present invention. It will be apparent to one skilled in the art that embodiments of the present invention may be practiced without these specific details. In other instances, well-known features, such as tool layouts or specific diode configurations, are not described in detail in order to not unnecessarily obscure embodiments of the present invention. Furthermore, it is to be understood that the various embodiments shown in the Figures are illustrative representations and are not necessarily drawn to scale. Additionally, other arrangements and configurations may not be explicitly disclosed in embodiments herein, but are still considered to be within the spirit and scope of the invention.

Modified MOCVD deposition techniques, such as plasma-assisted MOCVD may produce relatively more reactive species at low growth temperatures as compared with conventional MOCVD processes. For example, in accordance with an embodiment of the present invention, plasma-assisted MOCVD is used to provide a greater concentration of reactive nitrogen at low growth temperatures as compared with conventional MOCVD processes. As an example, a low temperature approach for depositing magnesium (Mg)-doped p-GaN is performed with a high concentration of active nitrogen (N) made available by plasma-assisted MOCVD. Since the availability of active nitrogen is not as heavily tied to reaction temperature in this approach, in an embodiment, nitrogen-rich GaN is deposited at relatively low growth temperatures, e.g., in the range of 570-720 degrees Celsius. However, in some embodiments it may also be desirable to form one or more of the group III-nitride layers at a growth temperature less than about 1150 degrees Celsius.

Also described herein are plasma-assisted MOCVD conditions that do not yield a substantial amount of free hydrogen. For example, in an embodiment, an extremely low ammonia flow, e.g., 1 SLM versus 4-50 SLM in conventional MOCVD, is used in a plasma. The species generated include a variety of species or radicals, such as hydrazine (N₂H₄) or NH₂ and NH radicals, but very little relative hydrogen produced. In an embodiment, by generating reactive nitrogen without the added generation of substantial free hydrogen, otherwise inhibiting reactions are mitigated or eliminated.

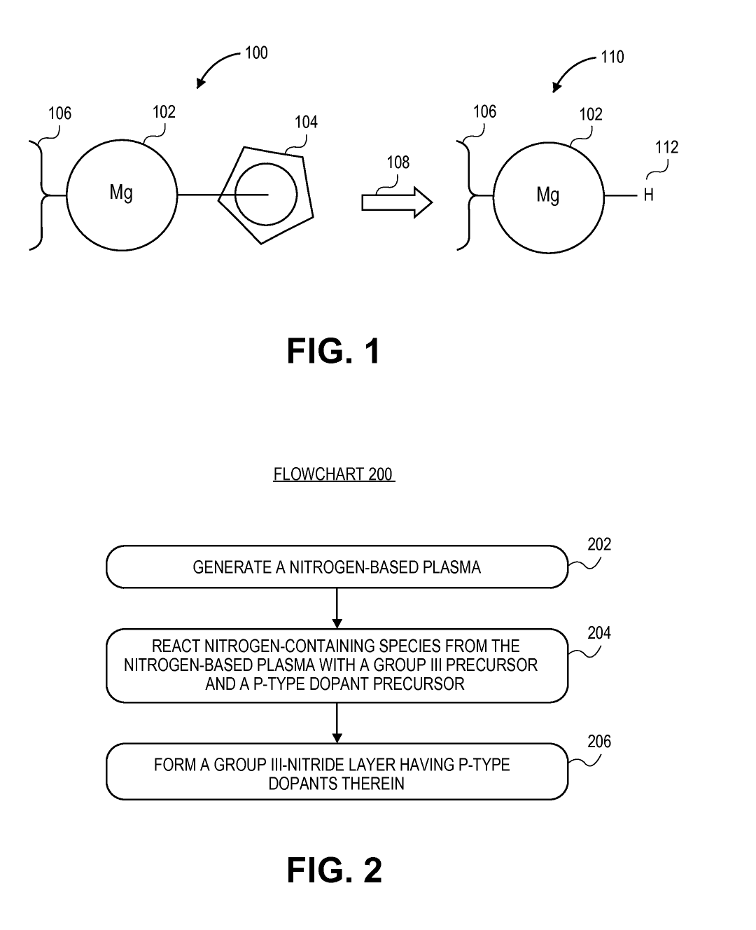

As an example of potential inhibiting behavior of free hydrogen, FIG. 1 illustrates transformation of a magnesium dopant precursor molecule to form a Mg—H bond in the presence of excess hydrogen. Referring to FIG. 1, a p-type dopant precursor 100 includes a magnesium atom 102, a cyclopentadiene (Cp) substituent 104, and one or more like or other substituents 106. Upon reaction 108 with free hydrogen or free hydrogen radicals, p-type dopant precursor 100 is transformed to a new molecule 110 with a hydrogen substituent 112 having taken the place of the Cp substituent 104. Such a mechanism may render the p-type dopant precursor 100 less effective or ineffective for doping in a MOCVD process. However, in accordance with an embodiment of the present invention, a plasma-assisted process to generate active nitrogen is used to and prevents substantial Mg—H complex formation since less relative hydrogen is generated.

At least some embodiments described herein provide MOCVD temperature regimes lower than the temperatures typically associated with conventional MOCVD. In an example, lowering growth temperature for p-GaN deposition on an InGaN layer may be effective for preventing damage to InGaN multi-quantum wells (MQWs) since thermal stability of InGaN is lower than GaN. In an embodiment, since the deposition is performed at a lower temperature, however, subsequent annealing of the deposited film may be performed. For example, if magnesium (Mg) activation is required, thermal annealing or low energy e-beam irradiation of the deposited film including Mg may activate the Mg. In at least some embodiments, using in-situ generated hydrazine provides a low energy pathway to group III-nitride formation. Thus, in some embodiments, a relatively low temperature deposition process is used. It is to be understood that the hydrazine may break-down prior to actual reaction with a group III precursor and, as such, a fragment of hydrazine is responsible for actual nitrogen delivery.

Dopant materials and the dopant concentration therein typically determine the conductivity type and the free carrier concentration of a semiconductor layer. Use of both conductivity types in one material may render p-n junction formation possible, which is a basic requirement for numerous electronic or optoelectronic devices, and group III-N based devices in particular. High doping levels may be crucial for proper device operation and performance. Doping level may determine turn-on and operating voltage, parameters of contacts, current injection efficiency, or current spreading, among other performance parameters.

Group II-elements predominantly occupy group III site due to their valence electron configuration, providing a good approach to forming p-type group III-nitrides. Group IV-elements could occupy group III site resulting in n-type group III-nitrides or, in case of occupying anion sites, a p-type material. Group IV species are unique in their ability to substitute either cation or anion site, resulting either in excess electrons (n-type) or a deficit of electrons (p-type), respectively. Accordingly, group II, and magnesium in particular, is often selected to consistently fabricate p-type group III-nitride material layers. However, effective doping levels may be as high as 10̂19-20 cm-3 Mg incorporation to result in a hole concentration of approximately 10̂18 cm-3. Common issues associated with magnesium-based p-doping may include one or more of: (a) compensation by native point defects, such as nitrogen vacancies V_{N} which act as single donors and are considered to be a serious source of compensation in p-type GaN, (b) compensation by foreign impurities, such as C and O in case of MOCVD p-GaN, and (c) Mg acceptors compensation by hydrogen due to Mg—H complex formation.

Described herein are methods of fabricating p-type group III-nitride materials. In one embodiment, a method includes generating a nitrogen-based plasma. Nitrogen-containing species from the nitrogen-based plasma are reacted with a group III precursor and a p-type dopant precursor in a MOCVD chamber. From the reacting, a group III-nitride layer including p-type dopants is formed above a substrate.

Also disclosed herein are process tools for fabricating p-type group III-nitride materials. In one embodiment, a process tool includes a plasma source for generating a nitrogen-based plasma. An MOCVD chamber is included for reacting nitrogen-containing species from the nitrogen-based plasma with a group III precursor and a p-type dopant precursor to form a group III-nitride layer including p-type dopants above a substrate.

Light-emitting diodes (LEDs) and related devices may be fabricated from layers of, e.g., p-type group III-V films, especially p-type group III-nitride films. Some embodiments of the present invention relate to forming p-type (e.g., magnesium doped) gallium nitride (GaN) layers in a dedicated chamber of a fabrication tool, such as in a dedicated MOCVD chamber. In some embodiments of the present invention, p-type GaN is a binary GaN film, but in other embodiments, p-type GaN is a ternary film (e.g., p-type InGaN, p-type AlGaN) or is a quaternary film (e.g., p-type InAlGaN). In at least some embodiments, the p-type group III-nitride material layers are formed epitaxially. They may be formed directly on a substrate or on a buffers layer disposed on a substrate.

In an aspect of the present invention, a p-type group III-nitride material layer is formed by a MOCVD process in conjunction with a nitrogen-based plasma. For example, FIG. 2 is a Flowchart 200 representing operations in a method of fabricating a p-type group III-nitride material, in accordance with an embodiment of the present invention.

Referring to operation 202 of Flowchart 200, a method includes generating a nitrogen-based plasma.

In an embodiment, generating the nitrogen-based plasma includes generating the nitrogen-based plasma in the MOCVD chamber. In one such embodiment, the nitrogen-based plasma is based on ammonia (NH₃) gas. In another such embodiment, the nitrogen-based plasma is based on a combination of hydrogen (H₂) gas and nitrogen (N₂) gas.

In another embodiment, generating the nitrogen-based plasma includes generating the nitrogen-based plasma remote to the MOCVD chamber. In one such embodiment, the nitrogen-based plasma is based on ammonia (NH₃) gas. In another such embodiment, the nitrogen-based plasma is based on a combination of hydrogen (H₂) gas and nitrogen (N₂) gas.

In an embodiment, hydrazine (N₂H₄), NH, or NH₂ species are generated in the nitrogen-based plasma. The specific conditions suitable for high concentration hydrazine, NH, or NH₂ species formation may differ from conventional MOCVD conditions. For example, in an embodiment, a plasma based on ammonia or based on a combination of H₂ and N₂ gas flows is used to produce an amount of hydrazine, NH, or NH₂ species sufficient to provide hydrazine, NH, or NH₂ species as the primary nitrogen delivery source. This approach may differ from conventional N₂-based plasmas which may use a small amount of H₂ gas as a minor catalyst or scrubber gas. With respect to ammonia-based plasma conditions for high concentration hydrazine formation, conventional approaches may yield too much free hydrogen on break-down of NH3, potentially inhibiting the p-type dopant precursor, as described above.

Referring to operation 204 of Flowchart 200, the method further includes reacting nitrogen-containing species from the nitrogen-based plasma with a group III precursor and a p-type dopant precursor in a MOCVD chamber.

In an embodiment, the reacting is performed at a temperature approximately in the range of 570-720 degrees Celsius. This range provides a relatively low temperature range as compared with conventional plasma-based processes. In one such embodiment, the temperature is approximately 670 degrees Celsius.

Referring to operation 206 of Flowchart 200, the method further includes forming, from the reacting, a group III-nitride layer including p-type dopants above a substrate. In an embodiment, the p-type dopant precursor is a magnesium-based precursor, the group III precursor is a gallium-based precursor, and the group III-nitride layer including p-type dopants is a gallium nitride layer including magnesium dopants.

In accordance with an embodiment of the present invention, a method of fabricating a p-type group III-nitride material further includes activating the p-type dopants in the group III-nitride layer to form a p-type doped group III-nitride layer. In one such embodiment, the activating includes the activating comprises exposing the group III-nitride layer to a low energy e-beam irradiation. In another such embodiment, the activating includes thermally annealing the group III-nitride layer.

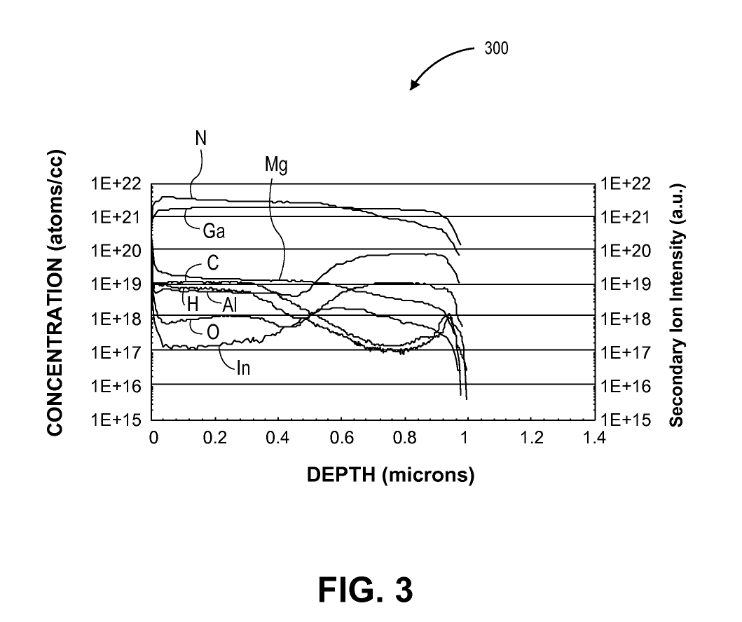

In accordance with embodiments of the present invention, a p-type group III-nitride may be fabricated to have high −p-type dopant concentration. For example, FIG. 3 includes a SIMS depth profile plot 300 for fabricated Mg-doped GaN, in accordance with an embodiment of the present invention.

Referring to plot 302, single crystal p-GaN has been demonstrated on MOCVD GaN templates, AlN buffer on sapphire, and on silicon substrates. The magnesium incorporation is approximately in the range of 1-2 E19 cm⁻³. It was observed that fewer N vacancies V_{N} existed as compared with N-rich GaN. Such a result may be selected as having a significant positive impact on electrical or optical properties or the resulting film and for enhanced doping levels in general. It was also observed that some H—Mg correlation existed, possibly indicating that at least some Mg—H complex formation is still in play, and that perhaps some optimization of H₂/N₂ and/or NH₃ flow rates should be performed. However, relative to conventional processes and films, the extent of H—Mg formation was significantly reduced. Also, above fabrication was performed at approximately 670 degrees Celsius. This reaction temperature is lower than conventional processing temperatures and may be at least somewhat responsible for the desirable reduction in N vacancies. Furthermore, under such conditions, favorable Ga substitution by Mg is enhanced resulting in significant concentrations of electrically active Mg. The resulting film exhibits reduced self-compensation otherwise caused by deep donor formation, Mg_{Ga}—V_{N}.

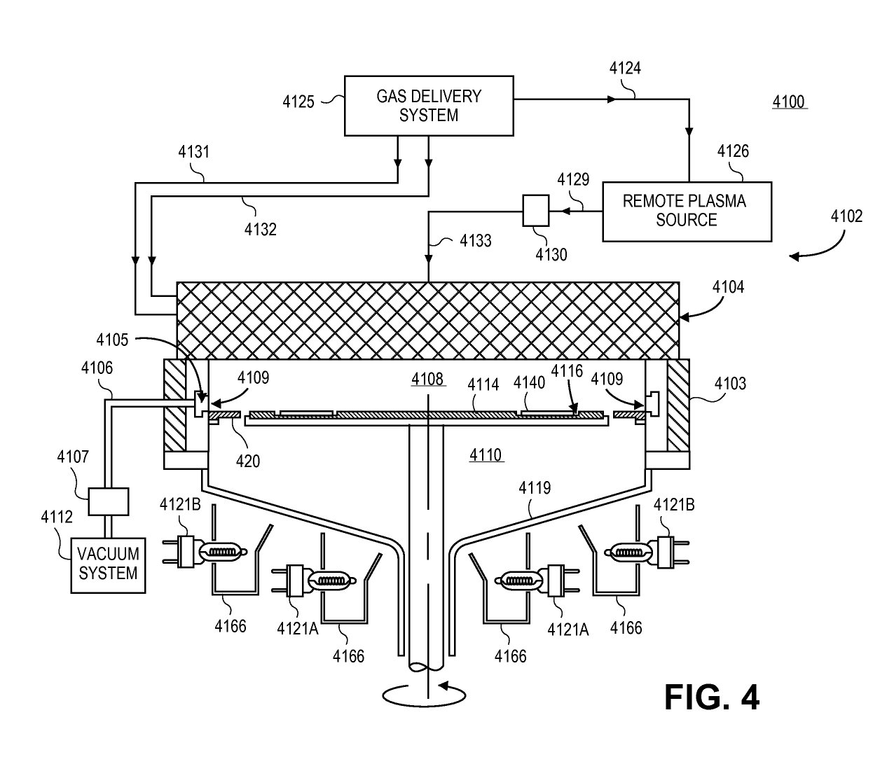

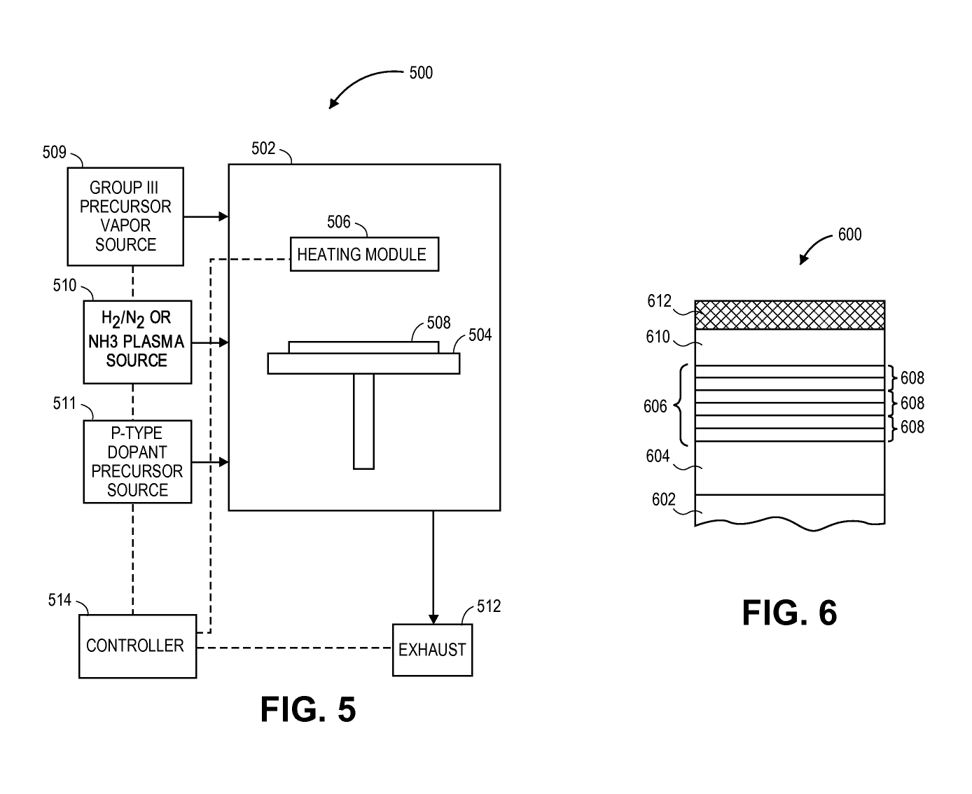

In another aspect of the present invention, as exemplified in more detail in association with FIGS. 4 and 5 below, a process tool for fabricating a p-type group III-nitride material is provided.

In an embodiment, such a process tool includes a plasma source for generating a nitrogen-based plasma. The process tool also includes a MOCVD chamber for reacting nitrogen-containing species from the nitrogen-based plasma with a group III precursor and a p-type dopant precursor to form a group III-nitride layer including p-type dopants above a substrate.

In an embodiment, the plasma source is located in the MOCVD chamber. In an embodiment, the plasma source is located remote to the MOCVD chamber. In an embodiment, the plasma source is for generating a plasma based on ammonia (NH₃) gas. In an embodiment, the plasma source is for generating a plasma based on a combination of hydrogen (H₂) gas and nitrogen (N₂) gas. In an embodiment, the process tool further includes an apparatus for exposing the group III-nitride layer to a low energy e-beam irradiation. In an embodiment, the process tool further includes an apparatus for thermally annealing the group III-nitride layer.

An example of an MOCVD deposition chamber which may be utilized for fabrication of p-type group III-nitride materials, in accordance with embodiments of the present invention, is illustrated and described with respect to FIG. 4.

FIG. 4 is a schematic cross-sectional view of an MOCVD chamber according to an embodiment of the invention. Exemplary systems and chambers that may be adapted to practice the present invention are described in U.S. patent application Ser. No. 11/404,516, filed on Apr. 14, 2006, and Ser. No. 11/429,022, filed on May 5, 2006, both of which are incorporated by reference in their entireties.

The apparatus 4100 shown in FIG. 4 comprises a chamber 4102, a gas delivery system 4125, a remote plasma source 4126, and a vacuum system 4112. The chamber 4102 includes a chamber body 4103 that encloses a processing volume 4108. A showerhead assembly 4104 is disposed at one end of the processing volume 4108, and a substrate carrier 4114 is disposed at the other end of the processing volume 4108. A lower dome 4119 is disposed at one end of a lower volume 4110, and the substrate carrier 4114 is disposed at the other end of the lower volume 4110. The substrate carrier 4114 is shown in process position, but may be moved to a lower position where, for example, the substrates 4140 may be loaded or unloaded. An exhaust ring 4120 may be disposed around the periphery of the substrate carrier 4114 to help prevent deposition from occurring in the lower volume 4110 and also help direct exhaust gases from the chamber 4102 to exhaust ports 4109. The lower dome 4119 may be made of transparent material, such as high-purity quartz, to allow light to pass through for radiant heating of the substrates 4140. The radiant heating may be provided by a plurality of inner lamps 4121A and outer lamps 4121B disposed below the lower dome 4119, and reflectors 4166 may be used to help control chamber 4102 exposure to the radiant energy provided by inner and outer lamps 4121A, 4121B. Additional rings of lamps may also be used for finer temperature control of the substrate 4140.

The substrate carrier 4114 may include one or more recesses 4116 within which one or more substrates 4140 may be disposed during processing. The substrate carrier 4114 may carry six or more substrates 4140. In one embodiment, the substrate carrier 4114 carries eight substrates 4140. It is to be understood that more or less substrates 4140 may be carried on the substrate carrier 4114. Typical substrates 4140 may include sapphire, silicon carbide (SiC), silicon, or gallium nitride (GaN). It is to be understood that other types of substrates 4140, such as glass substrates 4140, may be processed. Substrate 4140 size may range from 50 mm-100 mm in diameter or larger. The substrate carrier 4114 size may range from 200 mm-750 mm. The substrate carrier 4114 may be formed from a variety of materials, including SiC or SiC-coated graphite. It is to be understood that substrates 4140 of other sizes may be processed within the chamber 4102 and according to the processes described herein. The showerhead assembly 4104 may allow for more uniform deposition across a greater number of substrates 4140 and/or larger substrates 4140 than in traditional MOCVD chambers, thereby increasing throughput and reducing processing cost per substrate 4140.

The substrate carrier 4114 may rotate about an axis during processing. In one embodiment, the substrate carrier 4114 may be rotated at about 2 RPM to about 100 RPM. In another embodiment, the substrate carrier 4114 may be rotated at about 30 RPM. Rotating the substrate carrier 4114 aids in providing uniform heating of the substrates 4140 and uniform exposure of the processing gases to each substrate 4140.

The plurality of inner and outer lamps 4121A, 4121B may be arranged in concentric circles or zones (not shown), and each lamp zone may be separately powered. In one embodiment, one or more temperature sensors, such as pyrometers (not shown), may be disposed within the showerhead assembly 4104 to measure substrate 4140 and substrate carrier 4114 temperatures, and the temperature data may be sent to a controller (not shown) which can adjust power to separate lamp zones to maintain a predetermined temperature profile across the substrate carrier 4114. In another embodiment, the power to separate lamp zones may be adjusted to compensate for precursor flow or precursor concentration non-uniformity. For example, if the precursor concentration is lower in a substrate carrier 4114 region near an outer lamp zone, the power to the outer lamp zone may be adjusted to help compensate for the precursor depletion in this region.

The inner and outer lamps 4121A, 4121B may heat the substrates 4140 to a temperature of about 400 degrees Celsius to about 1200 degrees Celsius. It is to be understood that the invention is not restricted to the use of arrays of inner and outer lamps 4121A, 4121B. Any suitable heating source may be utilized to ensure that the proper temperature is adequately applied to the chamber 4102 and substrates 4140 therein. For example, in another embodiment, the heating source may comprise resistive heating elements (not shown) which are in thermal contact with the substrate carrier 4114.

A gas delivery system 4125 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 4102. Different gases, such as precursor gases, carrier gases, purge gases, cleaning/etching gases or others may be supplied from the gas delivery system 4125 to separate supply lines 4131, 4132, and 4133 to the showerhead assembly 4104. The supply lines 4131, 4132, and 4133 may include shut-off valves and mass flow controllers or other types of controllers to monitor and regulate or shut off the flow of gas in each line.

A conduit 4129 may receive cleaning/etching gases from a remote plasma source 4126. The remote plasma source 4126 may receive gases from the gas delivery system 4125 via supply line 4124, and a valve 4130 may be disposed between the showerhead assembly 4104 and remote plasma source 4126. The valve 4130 may be opened to allow a cleaning and/or etching gas or plasma to flow into the showerhead assembly 4104 via supply line 4133 which may be adapted to function as a conduit for a plasma. In another embodiment, apparatus 4100 may not include remote plasma source 4126 and cleaning/etching gases may be delivered from gas delivery system 4125 for non-plasma cleaning and/or etching using alternate supply line configurations to shower head assembly 4104.

The remote plasma source 4126 may be a radio frequency or microwave plasma source adapted for chamber 4102 cleaning and/or substrate 4140 etching. Cleaning and/or etching gas may be supplied to the remote plasma source 4126 via supply line 4124 to produce plasma species which may be sent via conduit 4129 and supply line 4133 for dispersion through showerhead assembly 4104 into chamber 4102. Gases for a cleaning application may include fluorine, chlorine or other reactive elements.

In another embodiment, the gas delivery system 4125 and remote plasma source 4126 may be suitably adapted so that precursor gases may be supplied to the remote plasma source 4126 to produce plasma species which may be sent through showerhead assembly 4104 to deposit CVD layers, such as group films, for example, on substrates 4140. In general, a plasma, which is a state of matter, is created by the delivery of electrical energy or electromagnetic waves (e.g., radio frequency waves, microwaves) to a process gas (e.g., precursor gases) to cause it to at least partially breakdown to form plasma species, such as ions, electrons and neutral particles (e.g., radicals). In one example, a plasma is created in an internal region of the plasma source 4126 by the delivery electromagnetic energy at frequencies less than about 100 gigahertz (GHz). In another example, the plasma source 4126 is configured to deliver electromagnetic energy at a frequency between about 0.4 kilohertz (kHz) and about 200 megahertz (MHz), such as a frequency of about 162 megahertz (MHz), at a power level less than about 4 kilowatts (kW). It is believed that the formed plasma enhances the formation and activity of the precursor gas(es) so that the activated gases, which reach the surface of the substrate(s) during the deposition process can rapidly react to form a layer that has improved physical and electrical properties.

A purge gas (e.g., nitrogen) may be delivered into the chamber 4102 from the showerhead assembly 4104 and/or from inlet ports or tubes (not shown) disposed below the substrate carrier 4114 and near the bottom of the chamber body 4103. The purge gas enters the lower volume 4110 of the chamber 4102 and flows upwards past the substrate carrier 4114 and exhaust ring 4120 and into multiple exhaust ports 4109 which are disposed around an annular exhaust channel 4105. An exhaust conduit 4106 connects the annular exhaust channel 4105 to a vacuum system 4112 which includes a vacuum pump (not shown). The chamber 4102 pressure may be controlled using a valve system 4107 which controls the rate at which the exhaust gases are drawn from the annular exhaust channel 4105.

FIG. 5 illustrates a system suitable for fabrication of p-type group III-nitride materials, in accordance with an embodiment of the present invention.

Referring to FIG. 5, the system 500 may include a deposition chamber 502 that includes a substrate support 504 and a heating module 506. The substrate support 504 may be adapted to support a substrate 508 during film formation within the chamber 502, and the heating module 506 may be adapted to heat the substrate 508 during film formation within the deposition chamber 502. More than one heating module, and/or other heating module locations may be used. The heating module 506 may include, for example, a lamp array or any other suitable heating source and/or element.

The system 500 may also include a group III, e.g., gallium, vapor source 509, a N₂/H₂ or NH₃ plasma source 510, a p-type dopant precursor source 511, and an exhaust system 512 coupled to the deposition chamber 502. The system 500 may also include a controller 514 coupled to the deposition chamber 502, the group III vapor source 509, the N₂/H₂ or NH₃ plasma source 510, the p-type dopant precursor source 511, and/or the exhaust system 512. The exhaust system 512 may include any suitable system for exhausting waste gases, reaction products, or the like from the chamber 502, and may include one or more vacuum pumps. The N₂/H₂ or NH₃ plasma source 510 may, in accordance with an embodiment of the present invention, be suitable to provide a substantial amount of nitrogen-containing species for reaction with vapor for the group III vapor source 509 and with p-type dopant precursors from the p-type dopant precursor source 511. The N₂/H₂ or NH₃ plasma source 510 may be used to generate a plasma in the deposition chamber or remotely and introduced into the deposition chamber.

The controller 514 may include one or more microprocessors and/or microcontrollers, dedicated hardware, a combination the same, etc., that may be employed to control operation of the deposition chamber 502, the group III vapor source 509, the N₂/H₂ or NH₃ plasma source 510, the p-type dopant precursor source 511, and/or the exhaust system 512. In at least one embodiment, the controller 514 may be adapted to employ computer program code for controlling operation of the system 500. For example, the controller 514 may perform or otherwise initiate one or more of the operations of any of the methods/processes described herein, including the method described in association with Flowchart 200. Any computer program code that performs and/or initiates such operations may be embodied as a computer program product. Each computer program product described herein may be carried by a medium readable by a computer (e.g., a floppy disc, a compact disc, a DVD, a hard drive, a random access memory, etc.).

Group III precursor vapor may be created by placing an elemental group III species into a vessel, such as a crucible, and heating the vessel to melt the elemental group III species. The vessel may be heated to a temperature of from about 100 degrees Celsius to about 250 degrees Celsius. In some embodiments, nitrogen gas may be passed over the vessel containing the molten elemental group III species at a pressure of about 1 Torr and pumped to the process chamber. The nitrogen may be flowed at a rate of about 200 standard cubic centimeters per minute (sccm). The group III precursor vapor may be drawn into the process chamber by a vacuum. In an alternative embodiment, the substrate may be exposed to the group III precursor vapor, the N₂/H₂ or NH₃ based plasma and one or more of hydrogen and hydrogen chloride. The hydrogen and/or the hydrogen chloride may increase the rate of deposition. In another embodiment of the present invention, a group III-nitride film may be deposited on a substrate using a group III sesquichloride precursor and/or a group III hydride precursor.

A p-type group III-nitride layer fabricated in a MOCVD chamber may be used in the fabrication of a light-emitting diode device. For example, FIG. 6 illustrates a cross-sectional view of a gallium nitride (GaN)-based light-emitting diode (LED), in accordance with an embodiment of the present invention.

Referring to FIG. 6, a GaN-based LED 600 includes an n-type GaN template 604 (e.g., n-type GaN, n-type InGaN, n-type AlGaN, n-type InAlGaN) on a substrate 602 (e.g., planar sapphire substrate, patterned sapphire substrate (PSS), silicon substrate, silicon carbide substrate). The GaN-based LED 600 also includes a multiple quantum well (MQW), or active region, structure or film stack 606 on or above the n-type

GaN template 604 (e.g., an MQW composed of one or a plurality of field pairs of InGaN well/GaN barrier material layers 608, as depicted in FIG. 6). The GaN-based LED 600 also includes a p-type GaN (p-GaN) layer or film stack 610 on or above the MQW 606, and a metal contact or ITO layer 612 on the p-GaN layer.

It is to be understood that embodiments of the present invention are not limited to formation of layers on patterned sapphire substrates. Other embodiments may include the use of any suitable patterned single crystalline substrate upon which a group III nitride epitaxial film may be formed. The patterned substrate may be formed from a substrate, such as but not limited to a sapphire (Al₂O₃) substrate, a silicon carbide (SiC) substrate, a silicon on diamond (SOD) substrate, a quartz (SiO₂) substrate, a glass substrate, a zinc oxide (ZnO) substrate, a magnesium oxide (MgO) substrate, and a lithium aluminum oxide (LiAlO₂) substrate. Any well know method, such as masking and etching may be utilized to form features, such as posts, from a planar substrate to create a patterned substrate. In a specific embodiment, however, the patterned substrate is a (0001) patterned sapphire substrate (PSS). Patterned sapphire substrates may be ideal for use in the manufacturing of LEDs because they increase the light extraction efficiency which is extremely useful in the fabrication of a new generation of solid state lighting devices. Other embodiments include the use of planar (non-patterned) substrates, such as a planar sapphire substrate. In other embodiments, the approaches herein are used to provide a group III-material layer directly on a silicon substrate.

In some embodiments, growth of a p-type gallium nitride or related film on a substrate is performed along a (0001) Ga-polarity, N-polarity, or non-polar a-plane {112-0} or m-plane {101-0}, or semi-polar planes. In some embodiments, posts formed in a patterned growth substrate are round, triangular, hexagonal, rhombus shape, or other shapes effective for block-style growth. In an embodiment, the patterned substrate contains a plurality of features (e.g., posts) having a cone shape. In a particular embodiment, the feature has a conical portion and a base portion. In an embodiment of the present invention, the feature has a tip portion with a sharp point to prevent over growth. In an embodiment, the tip has an angle (Θ) of less than 145° and ideally less than 110°. Additionally, in an embodiment, the feature has a base portion which forms a substantially 90° angle with respect to the xy plane of the substrate. In an embodiment of the present invention, the feature has a height greater than one micron and ideally greater than 1.5 microns. In an embodiment, the feature has a diameter of approximately 3.0 microns. In an embodiment, the feature has a diameter height ratio of approximately less than 3 and ideally less than 2. In an embodiment, the features (e.g., posts) within a discrete block of features (e.g., within a block of posts) are spaced apart by a spacing of less than 1 micron and typically between 0.7 to 0.8 microns.

It is also to be understood that embodiments of the present invention need not be limited to p-GaN as a group III-V layer in an LED device, such as described in association with FIG. 6. For example, other embodiments may include any p-type group III-nitride epitaxial film that can be suitably deposited by MOCVD, or the like, using a nitrogen-based plasma. The p-type group III-nitride film may be a binary, ternary, or quaternary compound semiconductor film formed from a group III element or elements selected from gallium, indium and aluminum and nitrogen. That is, the p-type group III-nitride crystalline film can be any solid solution or alloy of one or more Group III element and nitrogen, such as but not limited to p-type GaN, AlN, InN, AlGaN, InGaN, InAlN, and InGaAlN.

However, in a specific embodiment, the group III-nitride film is a p-type gallium nitride (GaN) film. The p-type group III-nitride film can have a thickness between 2-500 microns and is typically formed between 2-15 microns. In an embodiment of the present invention, the p-type group III-nitride film has a thickness of at least 3.0 microns to sufficiently suppress threading dislocations. The p-type group III-nitride film can be p-typed doped using any p-type dopant such as but not limited Mg, Be, Ca, Sr, or any Group I or Group II element have two valence electrons. The group III-nitride film can be p-type doped to a conductivity level of between 1×10¹⁶ to 1×10²⁰ atoms/cm³.

It is to be understood that on the above processes may be performed in a dedicated chamber within a cluster tool, or other tool with more than one chamber, e.g. an in-line tool arranged to have a dedicated chamber for fabricating layers of an LED. It is also to be understood that embodiments of the present invention need not be limited to the fabrication of LEDs. For example, in another embodiment, devices other than LED devices may be fabricated by an MOCVD process using a nitrogen-based plasma and a p-type dopant source, such as but not limited to field-effect transistor (FET) devices.

It is also to be understood that other mechanisms to assist low temperature MOCVD may be considered within the spirit and scope of the present invention. For example, in accordance with another embodiment, laser-assisted MOCVD is used for providing nitrogen-containing species to react with a group III precursor and a p-type dopant precursor in a metal-organic chemical vapor deposition (MOCVD) chamber at relatively low temperatures.

Thus, plasma-assisted MOCVD fabrication of p-type group III-nitride materials has been disclosed. In accordance with an embodiment of the present invention, a method of fabricating a p-type group III-nitride material includes generating a nitrogen-based plasma. The method also includes reacting nitrogen-containing species from the nitrogen-based plasma with a group III precursor and a p-type dopant precursor in a MOCVD chamber. The method also includes forming, from the reacting, a group III-nitride layer including p-type dopants above a substrate. In one embodiment, generating the nitrogen-based plasma includes generating the nitrogen-based plasma in the MOCVD chamber. In one embodiment, generating the nitrogen-based plasma includes generating the nitrogen-based plasma remote to the MOCVD chamber.

What is claimed is:

1. A method of fabricating a p-type group III-nitride material, the method comprising:
generating a nitrogen-based plasma;
reacting nitrogen-containing species from the nitrogen-based plasma with a group III precursor and a p-type dopant precursor in a metal-organic chemical vapor deposition (MOCVD) chamber; and
forming, from the reacting, a group III-nitride layer including p-type dopants above a substrate.

2. The method of claim 1, wherein generating the nitrogen-based plasma comprises generating the nitrogen-based plasma in the MOCVD chamber.

3. The method of claim 2, wherein the nitrogen-based plasma is based on ammonia (NH₃) gas.

4. The method of claim 2, wherein the nitrogen-based plasma is based on a combination of hydrogen (H₂) gas and nitrogen (N₂) gas.

5. The method of claim 1, wherein generating the nitrogen-based plasma comprises generating the nitrogen-based plasma remote to the MOCVD chamber.

6. The method of claim 5, wherein the nitrogen-based plasma is based on ammonia (NH₃) gas.

7. The method of claim 5, wherein the nitrogen-based plasma is based on a combination of hydrogen (H₂) gas and nitrogen (N₂) gas.

8. The method of claim 1, the method further comprising:
activating the p-type dopants in the group III-nitride layer to form a p-type doped group III-nitride layer.

9. The method of claim 8, wherein the activating comprises exposing the group III-nitride layer to a low energy e-beam irradiation.

10. The method of claim 8, wherein the activating comprises thermally annealing the group III-nitride layer.

11. The method of claim 1, wherein the reacting is performed at a temperature approximately in the range of 570-720 degrees Celsius.

12. The method of claim 11, wherein the temperature is approximately 670 degrees Celsius.

13. The method of claim 1, wherein the p-type dopant precursor is a magnesium-based precursor, the group III precursor is a gallium-based precursor, and the group III-nitride layer including p-type dopants is a gallium nitride layer including magnesium dopants.

14. A process tool for fabricating a p-type group III-nitride material, the process tool comprising:
a plasma source for generating a nitrogen-based plasma; and
a metal-organic chemical vapor deposition (MOCVD) chamber for reacting nitrogen-containing species from the nitrogen-based plasma with a group III precursor and a p-type dopant precursor.

15. The process tool of claim 14, wherein the plasma source is located in the MOCVD chamber.

16. The process tool of claim 14, wherein the plasma source is located remote to the MOCVD chamber.

17. The process tool of claim 14, wherein the plasma source is for generating a plasma based on ammonia (NH₃) gas.

18. The process tool of claim 14, wherein the plasma source is for generating a plasma based on a combination of hydrogen (H₂) gas and nitrogen (N₂) gas.

19. The process tool of claim 14, wherein the process tool further comprises an apparatus for exposing the group III-nitride layer to a low energy e-beam irradiation.

20. The process tool of claim 14, wherein the process tool further comprises an apparatus for thermally annealing the group III-nitride layer.

21. The process tool of claim 14, wherein reacting nitrogen-containing species from the nitrogen-based plasma with a group III precursor and a p-type dopant precursor is for forming a group III-nitride layer including p-type dopants above a substrate.
